(19) United States
(12) Patent Application Publication
(10) Pub. No.: US 2025/0248231 A1
(43) Pub. Date: Jul. 31, 2025

(54) DISPLAY DEVICE AND METHOD OF MANUFACTURING THE SAME

(71) Applicant: Samsung Display Co., Ltd., Yongin-Si (KR)

(72) Inventors: EOK SU KIM, Yongin-si (KR); SOYOUNG KOO, Yongin-si (KR); HYUNGJUN KIM, Yongin-si (KR)

(21) Appl. No.: 19/037,293

(22) Filed: Jan. 27, 2025

(30) Foreign Application Priority Data
Jan. 31, 2024 (KR) 10-2024-0014725

(51) Int. Cl. H10K 59/123; H10K 59/12

(52) U.S. Cl. CPC H10K 59/123; H10K 59/1201

(57) ABSTRACT

An electronic device includes a base substrate, a transistor disposed on the base substrate and including a semiconductor pattern including a source area, an active area, and a drain area and a gate electrode, a gate insulating pattern disposed on the semiconductor pattern, and a connection electrode disposed on the gate insulating pattern and electrically connected to the semiconductor pattern. A first hole extends through the transistor and is disposed adjacent to one of the source area and the drain area, the connection electrode is disposed on the same layer as the gate electrode, and the connection electrode comprises a protrusion pattern protruded towards the active area when viewed in a plane.

### CROSS-REFERENCE TO RELATED APPLICATION(S)

This application claims priority to and the benefit of Korean Patent Application No. 10-2024-0014725, filed on Jan. 31, 2024 in the Korean Intellectual Property Office, the disclosure of which is incorporated by reference herein in its entirety.

### BACKGROUND

### 1. Field

The present disclosure relates to an electronic device and a method of manufacturing the same. More particularly, the present disclosure relates to an electronic device including a connection electrode and a method of manufacturing the electronic device.

### 2. Description of Related Art

Multimedia electronic devices, such as televisions, mobile phones, tablet computers, computers, navigation units, and game units, include a display panel to display images. The display panel includes pixels displaying the images, and each of the pixels includes a light emitting element emitting a light and a driving element connected to the light emitting element.

The light emitting element and the driving element of the display panel are formed by stacking thin layers and pattering the thin layers using a mask. Since a display panel manufacturing process using a mask incurs a lot of costs, it is necessary to reduce the number of masks used to manufacture a electronic device by simplifying the display panel manufacturing process. In addition, it is required to manufacture the display panel with reliability while simplifying the manufacturing process.

### SUMMARY

The present disclosure provides an electronic device with simplified manufacturing process and improved display quality.

The present disclosure provides a method of manufacturing the electronic device.

Embodiments of the inventive concept provide an electronic device including a base substrate, a transistor disposed on the base substrate and including a semiconductor pattern including a source area, an active area, and a drain area and a gate electrode, a gate insulating pattern disposed on the semiconductor pattern, and a connection electrode disposed on the gate insulating pattern and electrically connected to the semiconductor pattern. A first hole extends through the transistor and is disposed adjacent to one of the source area and the drain area, the connection electrode is disposed on the same layer as the gate electrode, and the connection electrode includes a protrusion pattern protruded towards the active area when viewed in a plane.

A plurality of first holes including the first hole are provided, and the protrusion pattern is disposed between the first holes.

The protrusion pattern includes a first protrusion pattern that extends in a direction parallel to a first direction from one of the source area and the drain area towards the active area.

The protrusion pattern includes a second protrusion pattern that extends from the first protrusion pattern in a direction parallel to a second direction intersecting the first direction.

The connection electrode is electrically connected to the source area or the drain area.

The protrusion pattern is electrically connected to the active area.

The protrusion pattern is disposed directly on the source area or the drain area.

The first hole does not overlap the protrusion pattern.

A plurality of protrusion patterns including the protrusion pattern are provided, and the protrusion patterns protrude radially around a center point.

A plurality of connection electrodes including the connection electrode are provided, and each of the connection electrodes includes a first connection electrode connected to the drain area and a second connection electrode connected to the source area.

The electronic device further includes a first conductive pattern and a second conductive pattern, which are disposed between the base substrate and the transistor and are spaced apart from each other when viewed in the plane. The first conductive pattern is electrically connected to the drain area via the first connection electrode, and the second conductive pattern is electrically connected to the source area via the second connection electrode.

Each of the source area and the drain area includes a first portion having a first conductivity and a second portion having a second conductivity lower than the first conductivity.

The protrusion pattern protrudes from the first portion.

The active area, the first portion, and the protrusion pattern are electrically connected to each other.

The electronic device further includes a light emitting element disposed on the connection electrode and including a first electrode connected to the connection electrode, a light emitting layer, and a second electrode. The connection electrode electrically connects the first electrode and the transistor.

Embodiments of the inventive concept provide an electronic device including a base substrate, a transistor disposed on the base substrate and including a semiconductor pattern including a source area, an active area, and a drain area and a gate electrode, a gate insulating pattern disposed on the semiconductor pattern, and a connection electrode disposed on the gate insulating pattern and electrically connected to the semiconductor pattern. A first hole extends through the transistor and is disposed adjacent to one of the source area and the drain area, the connection electrode is disposed on the same layer as the gate electrode, a plurality of first holes including the first hole are provided, and the connection electrode includes a protrusion pattern disposed between the first holes.

Embodiments of the inventive concept provide a method of manufacturing an electronic device. The method includes preparing a preliminary electronic device including a base substrate, a preliminary semiconductor pattern disposed on the base substrate and including a source area, an active area, and a drain area, and a gate insulating pattern disposed on the preliminary semiconductor pattern, forming a first opening through the gate insulating pattern to expose a first portion of the preliminary semiconductor pattern, forming a conductive layer on the gate insulating pattern, forming a second opening through the conductive layer to expose a portion of the first portion of the preliminary semiconductor pattern and to form a gate electrode and a connection electrode from the conductive layer, and forming a first hole disposed adjacent to one of the source area and the drain area through the preliminary semiconductor pattern to form a semiconductor pattern from the preliminary semiconductor pattern. The connection electrode includes a protrusion pattern that protrudes towards the active area when viewed in a plane.

The method further includes doping the first portion of the preliminary semiconductor pattern exposed through the first opening after forming the first opening.

The forming of the gate electrode and the connection electrode includes forming a photoresist layer through which a photo opening is defined on the conductive layer and etching the conductive layer.

The connection electrode is disposed on the gate insulating pattern and electrically connected to the semiconductor pattern, and the connection electrode is disposed on the same layer as the gate electrode.

According to the above, the connection electrode of the electronic device includes the protrusion pattern protruded to the active area, and a current flows through the protrusion pattern. Thus, when the current flows from the active area to the source area and the drain area, a resistance is reduced and a flow of the current becomes smoother.

According to the above, an additional process using a mask to form the connection electrode is not required, and the connection electrode, which includes the same material as a gate, serves as a source and a drain. Accordingly, the manufacturing process is simplified and the manufacturing cost is reduced.

### BRIEF DESCRIPTION OF THE DRAWINGS

The above and other advantages of the present disclosure will become readily apparent by reference to the following detailed description when considered in conjunction with the accompanying drawings.

FIG. 1 is a perspective view of an electronic device according to an embodiment of the present disclosure.

FIG. 2A is an exploded perspective view of an electronic device according to an embodiment of the present disclosure.

FIG. 2B is a cross-sectional view of a display module according to an embodiment of the present disclosure.

FIG. 3 is a plan view of a display panel according to an embodiment of the present disclosure.

FIG. 4 is a cross-sectional view taken along a line I-I′ of FIG. 3.

FIG. 5 is a plan view corresponding to a circuit layer of FIG. 4.

FIG. 6 is an enlarged plan view of an area AA′ of FIG. 5.

FIG. 7A is a cross-sectional view taken along a line II-II′ of FIG. 6.

FIG. 7B is a cross-sectional view taken along a line III-III′ of FIG. 6.

FIG. 8 is a plan view corresponding to a circuit layer of FIG. 4 according to an embodiment of the present disclosure.

FIG. 9 is an enlarged plan view of an area BB′ of FIG. 8.

FIG. 10 is a plan view corresponding to a circuit layer of FIG. 4 according to an embodiment of the present disclosure.

FIG. 11 is an enlarged plan view of an area CC′ of FIG. 10.

FIG. 12 is a plan view corresponding to a circuit layer of FIG. 4 according to an embodiment of the present disclosure.

FIG. 13 is an enlarged plan view of an area DD′ of FIG. 12.

FIGS. 14, 15, 16, 17, 18, 19, 20, 21, 22, and 23 are cross-sectional views illustrating a method of manufacturing an electronic device according to an embodiment of the present disclosure.

### DETAILED DESCRIPTION

In the present disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present disclosure will be described with reference to accompanying drawings.

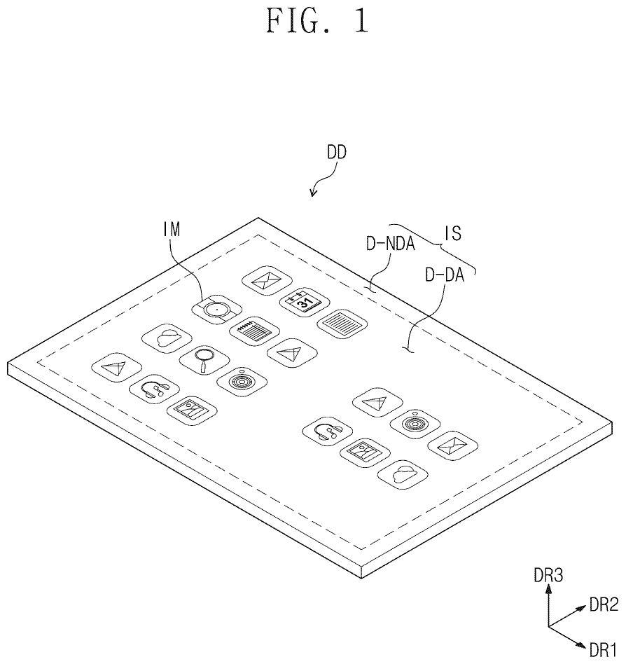

FIG. 1 is a perspective view of an electronic device DD according to an embodiment of the present disclosure.

Referring to FIG. 1, the electronic device DD may be activated in response to electrical signals and may display an image IM. The electronic device DD may include various embodiments to provide the image IM to a user. As an example, the electronic device DD may be applied to a large-sized electronic device, such as a television set, an outdoor billboard, etc., and a small and medium-sized electronic device, such as a monitor, a mobile phone, a tablet computer, a navigation unit, a game unit, etc. However, these are merely examples, and the electronic device DD may be applied to other electronic devices as long as they do not depart from the concept of the present disclosure.

The electronic device DD may have a rectangular shape with long sides extending in a first direction DR1 and short sides extending in a second direction DR2 intersecting the first direction DR1 when viewed in a plane. However, the shape of the electronic device DD should not be limited to the rectangular shape, and the electronic device DD may have a variety of shapes, such as a circular shape, a polygonal shape, etc.

The electronic device DD may display the image IM through a display surface IS toward a third direction DR3, which is substantially perpendicular to a plane defined by the first direction DR1 and the second direction DR2. A normal line direction of the display surface IS may be substantially parallel to the third direction DR3. The display surface IS through which the image IM is displayed may correspond to a front surface of the electronic device DD. The image IM may include a still image as well as a video. FIG. 1 shows application icons as a representative example of the image IM.

In the present embodiment, front (or upper) and rear (or lower) surfaces of each member of the electronic device DD may be defined with respect to the third direction DR3. The front and rear surfaces may be opposite to each other in the third direction DR3, and a normal line direction of each of the front and rear surfaces may be substantially parallel to the third direction DR3. A separation distance between the front and rear surfaces of each member in the third direction DR3 may correspond to a thickness of the member in the third direction DR3.

In the present disclosure, the expression “when viewed in a plane” may mean a state of being viewed in the third direction DR3. In the present disclosure, the expression “when viewed in a cross-section” may mean a state of being viewed in the first direction DR1 or the second direction DR2. Directions indicated by the first, second, and third directions DR1, DR2, and DR3 are relative to each other, and thus, the directions indicated by the first, second, and third directions DR1, DR2, and DR3 may be changed to other directions.

FIG. 1 shows the electronic device DD including the display surface IS that is flat as a representative example. However, the shape of the display surface IS of the electronic device DD should not be limited thereto or thereby, and the display surface IS may have a curved or three-dimensional shape.

The electronic device DD may be flexible. The term “flexible” used herein refers to the property of being able to be bent, from a structure that is completely bent to a structure that is bent at the scale of a few nanometers. For example, the flexible electronic device DD may be a curved electronic device or a foldable electronic device, however, the present disclosure should not be limited thereto or thereby. According to an embodiment, the electronic device DD may be rigid.

The display surface IS of the electronic device DD may include a display part D-DA and a non-display part D-NDA. The display part D-DA may be a part where the image IM is displayed within the front surface of the electronic device DD, and a user may view the image IM through the display part D-DA. In the present embodiment, the display part D-DA having a quadrangular shape in a plane is illustrated as a representative example, however, the display part D-DA may have a variety of shapes depending on a design of the electronic device DD.

The non-display part D-NDA may be a part where the image IM is not displayed within the front surface of the electronic device DD. The non-display part D-NDA may have a predetermined color and may block a light. The non-display part D-NDA may be disposed adjacent to the display part D-DA. As an example, the non-display part D-NDA may be disposed outside of the display part D-DA and may surround the display part D-DA, however, this is merely an example. The non-display part D-NDA may be defined adjacent to only one side of the display part D-DA or may be defined in a side surface rather than the front surface of the electronic device DD. According to an embodiment, the non-display part D-NDA may be omitted.

According to an embodiment, the electronic device DD may sense an external input applied thereto from the outside. The external input may include a variety of external inputs provided from the outside, such as pressure, temperature, light, etc. The external input may include a proximity input (e.g., a hovering input) applied when approaching close to or adjacent to the electronic device DD at a predetermined distance as well as a touch input, e.g., a touch by a hand of a user or a pen.

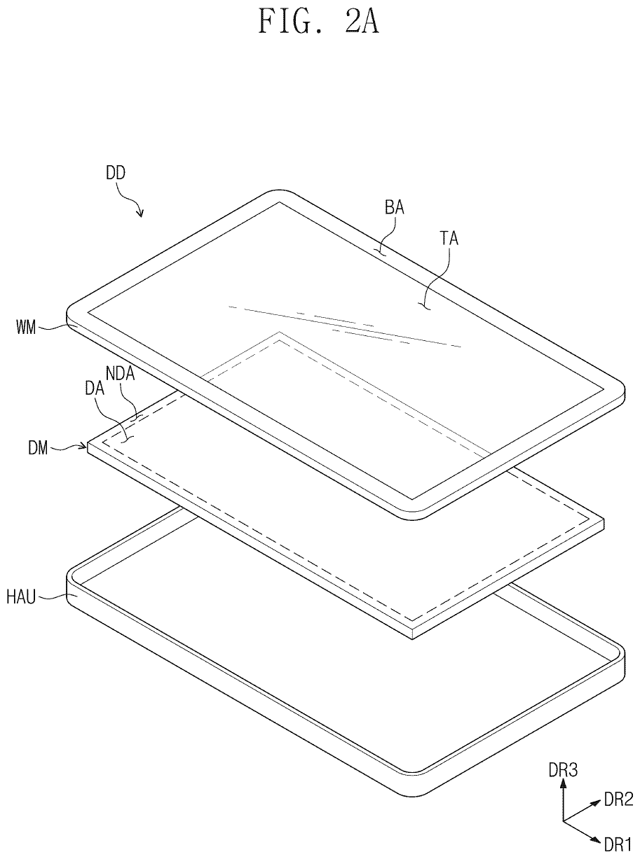

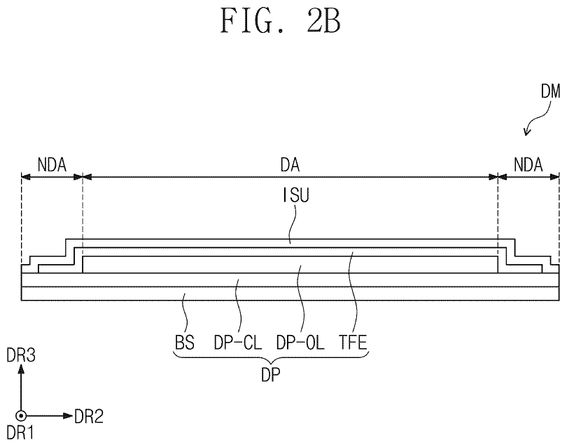

FIG. 2A is an exploded perspective view of the electronic device DD according to an embodiment of the present disclosure. FIG. 2B is a cross-sectional view of a display module DM according to an embodiment of the present disclosure.

Referring to FIGS. 2A and 2B, the electronic device DD may include a window WM, the display module DM, and a housing HAU. The display module DM may include a display panel DP and a light control member.

The window WM may be coupled with the housing HAU to form an external appearance of the electronic device DD and to provide an inner space in which components, e.g., the display module DM, of the electronic device DD are accommodated.

The window WM may be disposed on the display module DM. The window WM may protect the display module DM from external impacts. A front surface of the window WM may correspond to the display surface IS (see FIG. 1 for example) of the electronic device DD. The front surface of the window WM may include a transmission area TA and a bezel area BA.

The transmission area TA of the window WM may be an optically transparent area. The window WM may transmit the image provided from the display module DM through the transmission area TA, and the user may view the image. The transmission area TA of the window WM may correspond to the display part D-DA (see FIG. 1 for example) of the electronic device DD.

The window WM may include an optically transparent insulating material. As an example, the window WM may include a glass, sapphire, or plastic material. The window WM may have a single-layer or multi-layer structure. The window WM may further include functional layers, such as an anti-fingerprint layer, a phase control layer, a hard coating layer, etc., disposed on an optically transparent substrate.

The bezel area BA of the window WM may be obtained by depositing, coating, or printing a material having a predetermined color on a transparent substrate. The bezel area BA of the window WM may prevent components of the display module DM, which are disposed to overlap the bezel area BA, from being viewed from the outside. The bezel area BA may correspond to the non-display part D-NDA (see FIG. 1 for example) of the electronic device DD.

The display module DM may be disposed between the window WM and the housing HAU. The display module DM may display the image in response to electrical signals. The display module DM may include a display area DA and a non-display area NDA defined adjacent to the display area DA.

The display area DA may be activated in response to electrical signals and may display the image. The display area DA of the display module DM may overlap the transmission area TA of the window WM. In the present disclosure, the expression “An area/portion overlaps another area/portion.” should not be limited to meaning that “An area/portion has the same size and/or the same shape as those of another area/portion.” The image provided from the display area DA may be viewed from the outside through the transmission area TA.

The non-display area NDA may be defined adjacent to the display area DA. As an example, the non-display area NDA may surround the display area DA, however, it should not be limited thereto or thereby. According to an embodiment, the non-display area NDA may be defined in a variety of shapes. A driving circuit or a driving line to drive elements disposed in the display area DA, various signal lines to provide electrical signals to the elements, and pads may be disposed in the non-display area NDA. The non-display area NDA of the display module DM may overlap the bezel area BA of the window WM, and components of the display module DM, which are disposed in the non-display area NDA, may be prevented from being viewed from the outside by the bezel area BA.

The display panel DP according to an embodiment may be a light-emitting type display panel, however, it should not be particularly limited. For instance, the display panel DP may be an organic light emitting display panel, an inorganic light emitting display panel, or a quantum dot light emitting display panel. A light emitting layer of the organic light emitting display panel may include an organic light emitting material. A light emitting layer of the inorganic light emitting display panel may include an inorganic light emitting material. A light emitting layer of the quantum dot light emitting display panel may include a quantum dot and/or a quantum rod. Hereinafter, the organic light emitting display panel will be described as a representative example of the display panel DP.

The display panel DP may include a base substrate BS, a circuit layer DP-CL, a display element layer DP-OL, and an encapsulation layer TFE.

The base substrate BS may provide a base surface on which the circuit layer DP-CL is disposed. The base substrate BS may be a rigid substrate or a flexible substrate.

The circuit layer DP-CL may be disposed on the base substrate BS. The circuit layer DP-CL may include driving elements such as transistors, signal lines, and signal pads. The display element layer DP-OL may include light emitting elements disposed to overlap the display area DA. The light emitting elements of the display element layer DP-OL may be electrically connected to the driving elements of the circuit layer DP-CL and may emit a light through the display area DA in response to a signal from the driving element.

The encapsulation layer TFE may be disposed on the display element layer DP-OL and may encapsulate the light emitting elements. The encapsulation layer TFE may include a plurality of thin layers. The thin layers of the encapsulation layer TFE may improve an optical efficiency of the light emitting elements or may protect the light emitting elements.

A sensor layer ISU may be disposed on the display panel DP. The sensor layer ISU may sense the external input applied thereto from the outside. The external input may be a user input. The external input may include a variety of inputs provided by a part of the user's body, light, heat, pen, pressure, etc.

The sensor layer ISU may be formed on the display panel DP through successive processes. In this case, the sensor layer ISU may be disposed directly on the display panel DP. In the following descriptions, the expression “The sensor layer ISU is disposed directly on the display panel DP” means that no intervening elements are present between the sensor layer ISU and the display panel DP. That is, a separate adhesive member may not be disposed between the sensor layer ISU and the display panel DP.

According to an embodiment, the sensor layer ISU may be coupled with the display panel DP by an adhesive member. The adhesive member may include a conventional adhesive.

The housing HAU may be disposed under the display module DM and may accommodate the display module DM. The housing HAU may absorb impacts applied to the display module DM from the outside and may prevent a foreign substance and moisture from entering the display module DM, and thus, the display module DM may be protected by the housing HAU. According to an embodiment, the housing HAU may be provided in a form obtained by coupling a plurality of accommodating members.

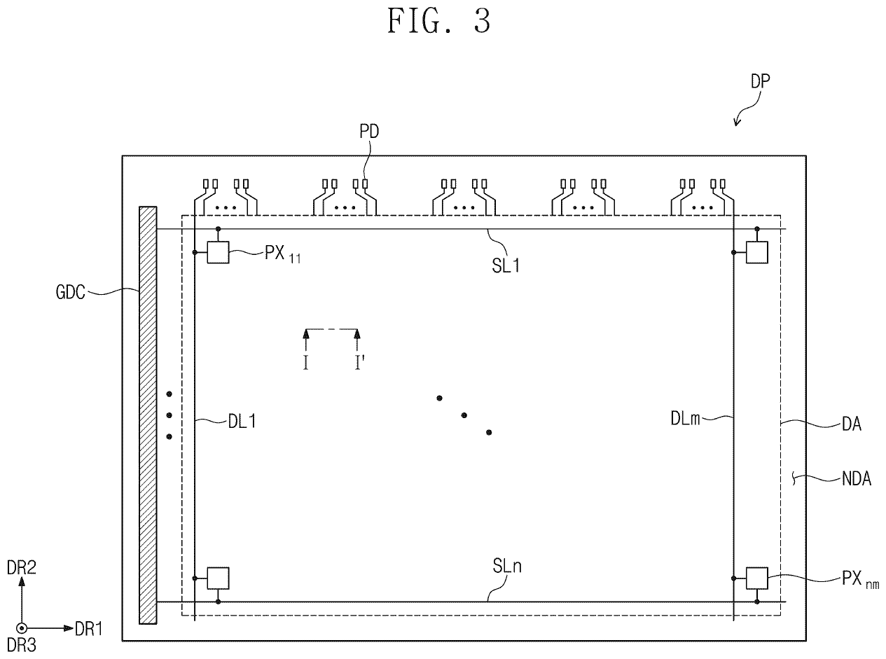

FIG. 3 is a plan view of the display panel DP according to an embodiment of the present disclosure.

Referring to FIG. 3, the display panel DP may include pixels PX11 to PXnm disposed in the display area DA and signal lines SL1 to SLn and DL1 to DLm electrically connected to the pixels PX11 to PXnm. The display panel DP may include a driving circuit GDC and pads PD, which are disposed in the non-display area NDA.

Each of the pixels PX11 to PXnm may include a pixel driving circuit configured to include the light emitting element, a plurality of transistors, e.g., a switching transistor, a driving transistor, etc., connected to the light emitting element, and a capacitor. Each of the pixels PX11 to PXnm may emit a light in response to an electrical signal applied thereto. FIG. 3 shows the pixels PX11 to PXnm arranged in a matrix form as a representative example, however, the arrangement of the pixels PX11 to PXnm should not be limited thereto or thereby.

The signal lines SL1 to SLn and DLI to DLm may include scan lines SL1 to SLn and data lines DL1 to DLm. Each of the pixels PX11 to PXnm may be connected to a corresponding scan line of the scan lines SL1 to SLn and a corresponding data line of the data lines DL1 to DLm. Meanwhile, more types of signal lines may be provided in the display panel DP depending on the configuration of the pixel driving circuit of the pixels PX11 to PXnm.

The driving circuit GDC may include a gate driving circuit. The gate driving circuit may generate gate signals and may sequentially output the gate signals to the scan lines SL1 to SLn. The gate driving circuit may further output another control signal to the pixel driving circuit of the pixels PX11 to PXnm.

The driving circuit GDC and the pixels PX11 to PXnm may include a plurality of transistors formed through a process, for instance, a low temperature polycrystalline silicon (LTPS) process, a low temperature polycrystalline oxide (LTPO) process, or an oxide semiconductor process.

The pads PD may be arranged in the non-display area NDA along one direction. The pads PD may be connected to a circuit board. Each of the pads PD may be connected to a corresponding signal line among the signal lines SL1 to SLn and DL1 to DLm and may be connected to corresponding pixels among the pixels PX11 to PXnm via the signal line. The pads PD may be provided integrally with the signal lines SL1 to SLn and DL1 to DLm, however, they should not be limited thereto or thereby. According to an embodiment, the pads PD may be disposed on a different layer from the signal lines SL1 to SLn and DL1 to DLm and may be connected to the signal lines SL1 to SLn and DL1 to DLm via a contact hole.

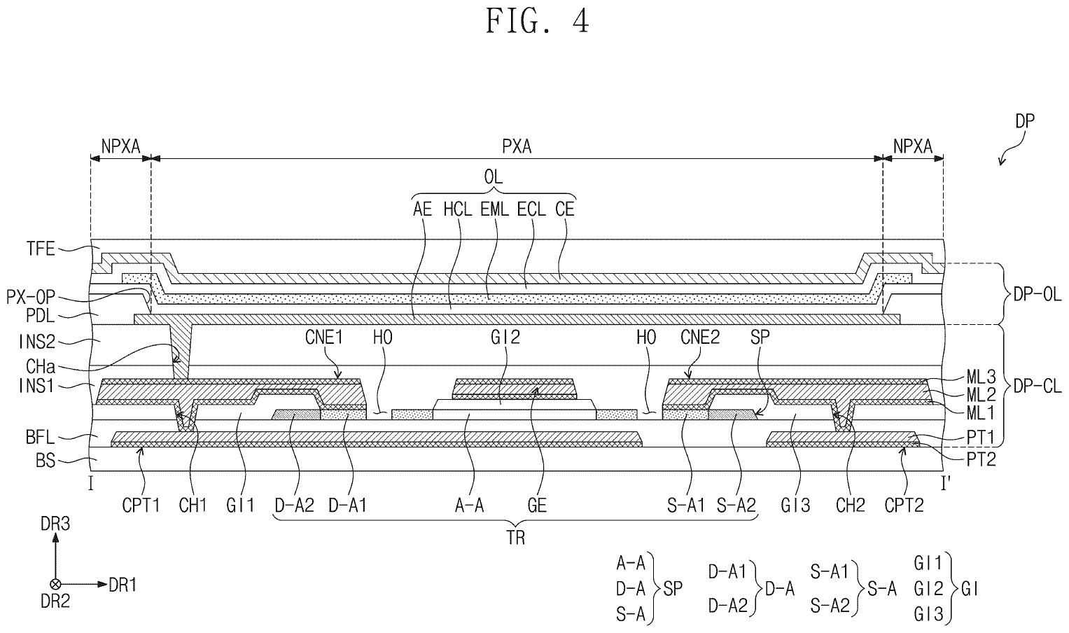

FIG. 4 is a cross-sectional view taken along a line I-I′ of FIG. 3.

Referring to FIG. 4, the display panel DP may include the base substrate BS, the circuit layer DP-CL, the display element layer DP-OL, and the encapsulation layer TFE.

The circuit layer DP-CL may include first and second conductive patterns CPT1 and CPT2, a transistor TR, connection electrodes CNE1 and CNE2, a buffer layer BFL, a gate insulating pattern GI, and insulating layers INS1 and INS2, which are disposed on the base substrate BS.

The first conductive pattern CPT1 and the second conductive pattern CPT2 may be disposed between the base substrate BS and the transistor TR and may be spaced apart from each other when viewed in the plane. The first conductive pattern CPT1 may be electrically connected to a drain area D-A via the first connection electrode CNE1. The second conductive pattern CPT2 may be electrically connected to a source area S-A via the second connection electrode CNE2.

Each of the first conductive pattern CPT1 and the second conductive pattern CPT2 may have a multi-layer structure. The first conductive pattern CPT1 and the second conductive pattern CPT2 may be formed of the same material and may have the same stack structure. As an example, each of the first conductive pattern CPT1 and the second conductive pattern CPT2 may include a first pattern layer PT1 and a second pattern layer PT2, which are stacked on the base substrate BS along a thickness direction, i.e., in the third direction DR3, however, the present disclosure should not be limited thereto or thereby. According to an embodiment, each of first and second conductive patterns CPT1 and CPT2 may have a single-layer structure or may have a multi-layer structure in which three or more pattern layers are stacked.

The first pattern layer PT1 and the second pattern layer PT2 may have different thicknesses from each other. As an example, the thickness of the first pattern layer PT1 may be smaller than the thickness of the second pattern layer PT2, however, the present disclosure should not be limited thereto or thereby.

Each of the first pattern layer PT1 and the second pattern layer PT2 may include one of molybdenum (Mo), aluminum (Al), chromium (Cr), gold (Au), titanium (Ti), nickel (Ni), neodymium (Nd), and copper (Cu) or an alloy thereof. As an example, the first pattern layer PT1 may include titanium (Ti), and the second pattern layer PT2 may include copper (Cu), however, the present disclosure should not be limited thereto or thereby.

The buffer layer BFL may be disposed on the base substrate BS to cover the first and second conductive patterns CPT1 and CPT2. The buffer layer BFL may include at least one inorganic layer.

The transistor TR may include a semiconductor pattern SP and a gate electrode GE. The semiconductor pattern SP may be disposed on the buffer layer BFL. An adhesion between the semiconductor pattern SP and the base substrate BS may be improved by the buffer layer BFL. The semiconductor pattern SP may include a semiconductor material, such as polycrystalline silicon, crystalline silicon, or metal oxide.

The source area S-A, an active area A-A, and the drain area D-A of the transistor TR may be formed from the semiconductor pattern SP. The semiconductor pattern SP may have different electrical properties depending on whether it is doped or not or whether a metal oxide is reduced or not. The source area S-A and the drain area D-A of the semiconductor pattern SP, which have a relatively high conductivity, may serve as an electrode or a signal line. A non-doped portion, a portion doped with a low doping concentration, or a non-reduced portion of the semiconductor pattern SP may correspond to the active area A-A, which has a relatively low conductivity. The active area A-A may be disposed between the source area S-A and the drain area D-A when viewed in the plane.

The drain area D-A may include a first drain area (or a first portion) D-A1 and a second drain area (or a second portion) D-A2. The first drain area D-A1 may have a conductivity higher than that of the second drain area D-A2. The first drain area D-A1 may have a first conductivity. The second drain area D-A2 may have a second conductivity lower than the first conductivity. The first drain area D-A1 may be doped at a higher concentration compared with the second drain area D-A2. Accordingly, when current flows in from the active area A-A, the current may mainly flow in through the first drain area D-A1.

The source area S-A may include a first source area (or a first portion) S-A1 and a second source area (or a second portion) S-A2. The first source area S-A1 may have a conductivity higher than that of the second source area S-A2. The first source area S-A1 may have a third conductivity. The second source area S-A2 may have a fourth conductivity lower than the third conductivity. The first source area S-A1 may be doped at a higher concentration compared with the second source area S-A2. Accordingly, when current flows in from the active area A-A, the current may mainly flow in through the first source area S-A1.

At least one hole HO may be defined through the semiconductor pattern SP in the source area S-A or the drain area D-A. The hole HO may be formed during an etching process of forming the connection electrodes CNE1 and CNE2 and the gate electrode GE. FIG. 4 shows a structure in which the holes HO are formed through the semiconductor pattern SP and spaced apart from each other as a representative example. Among the holes HO, one hole HO may be surrounded by the source area S-A when viewed in the plane, and another hole HO may be surrounded by the drain area D-A, however, the present disclosure should not be limited thereto or thereby. According to an embodiment, the hole HO may not be formed through the semiconductor pattern SP depending on the process of forming the circuit layer DP-CL.

The gate insulating pattern GI may be disposed on the buffer layer BFL. The gate insulating pattern GI may include at least one inorganic layer. The gate insulating pattern GI may include first, second, and third gate insulating patterns GI1, GI2, and GI3 spaced apart from each other. The first gate insulating pattern GI1 may cover the second drain area D-A2 of the drain area D-A and may be disposed above the first conductive pattern CPT1. The second gate insulating pattern GI2 may be disposed on the active area A-A. The second gate insulating pattern GI2 may correspond to the active area A-A. The third gate insulating pattern GI3 may cover the second source area S-A2 of the source area S-A.

The connection electrodes CNE1 and CNE2 may include the first connection electrode CNE1 and the second connection electrode CNE2. The first connection electrode CNE1 may be disposed on the first gate insulating pattern GI1. The first connection electrode CNE1 may be connected to the first conductive pattern CPT1 via a first contact hole CH1 defined through the buffer layer BFL and the first gate insulating pattern GI1. The first connection electrode CNE1 may be in contact with the first drain area D-A1 of the drain area D-A and may be electrically connected to the drain area D-A. The first drain area D-A1 and the first conductive pattern CPT1 may be electrically connected to each other by the first connection electrode CNE1. As the first conductive pattern CPT1 is electrically connected to the drain area D-A through the first drain area D-A1 with high conductivity, current transfer characteristics may be improved.

The second connection electrode CNE2 may be disposed on the third gate insulating pattern GI3. The second connection electrode CNE2 may be connected to the second conductive pattern CPT2 via a second contact hole CH2 defined through the buffer layer BFL and the third gate insulating pattern GI3. The second connection electrode CNE2 may be in contact with the first source area S-A1 of the source area S-A and may be electrically connected to the source area S-A. The source area S-A and the second conductive pattern CPT2 may be electrically connected to each other by the second connection electrode CNE2. The second connection electrode CNE2 may be connected to a power line that supplies a power to a light emitting element OL, and thus, may supply a first voltage to the transistor TR.

The gate electrode GE may be disposed on the second gate insulating pattern GI2. The gate electrode GE may overlap the active area A-A when viewed in the plane and may be spaced apart from the semiconductor pattern SP with the second gate insulating pattern GI2 interposed therebetween in the thickness direction.

The connection electrodes CNE1 and CNE2 may be spaced apart from the gate electrode GE when viewed in the plane. The connection electrodes CNE1 and CNE2 and the gate electrode GE may have a multi-layer structure in which conductive layers ML1, ML2, and ML3 including different materials from each other are stacked. The conductive layers ML1, ML2, and ML3 may include first, second, and third conductive layers ML1, ML2, and ML3. The first, second, and third conductive layers ML1, ML2, and ML3 may be stacked through a sputtering process, however, the present disclosure should not be limited thereto or thereby.

Each of the first, second, and third conductive layers ML1, ML2, and ML3 may include a metal material. As an example, each of the first, second, and third conductive layers ML1, ML2, and ML3 may include one of molybdenum (Mo), aluminum (Al), chromium (Cr), gold (Au), titanium (Ti), nickel (Ni), neodymium (Nd), copper (Cu), and indium tin oxide (ITO) or an alloy thereof. The first, second, and third conductive layers ML1, ML2, and ML3 may include different metal materials from each other. The second conductive layer ML2 may include a metal material with high conductivity, and the first and third conductive layers ML1 and ML3 respectively disposed under and on the second conductive layer ML2 may include a metal material with a corrosion resistance. As an example, the first conductive layer ML1 may include titanium (Ti), the second conductive layer ML2 may include copper (Cu), and the third conductive layer ML3 may include indium tin oxide (ITO), however, the present disclosure should not be limited thereto or thereby.

The first, second, and third conductive layers ML1, ML2, and ML3 may have different thicknesses from each other. As an example, the second conductive layer ML2 including the metal material with high conductivity may have the largest thickness among the first, second, and third conductive layers ML1, ML2, and ML3. Therefore, the connection electrodes CNE1 and CNE2 and the gate electrode GE, which are formed from the first, second, and third conductive layers ML1, ML2, and ML3, may have a low resistance and a high conductivity.

FIG. 4 shows a structure in which the connection electrodes CNE1 and CNE2 and the gate electrode GE have the multi-layer structure, e.g., a three-layer structure, as a representative example, however, the present disclosure should not be limited thereto or thereby. According to an embodiment, the connection electrodes CNE1 and CNE2 and the gate electrode GE may have a multi-layer structure with fewer or more number of layers than three or may have a single-layer structure.

The connection electrodes CNE1 and CNE2 and the gate electrode GE may be substantially simultaneously formed through the same process. The connection electrodes CNE1 and CNE2 and the gate electrode GE may have the same stack structure as each other. As an example, the connection electrodes CNE1 and CNE2 and the gate electrode GE may have the three-layer structure of Ti/Cu/ITO. As the connection electrodes CNE1 and CNE2 and the gate electrode GE are substantially simultaneously formed through the same process, manufacturing processes of the display panel DP may be simplified.

The first insulating layer INS1 may be disposed on the gate insulating pattern GI to cover the connection electrodes CNE1 and CNE2 and the gate electrode GE. The second insulating layer INS2 (or an insulating layer) may be disposed on the first insulating layer INS1. Each of the first insulating layer INS1 and the second insulating layer INS2 may include at least one inorganic layer or an organic layer. The inorganic layer may include at least one of aluminum oxide, titanium oxide, silicon oxide, silicon nitride, silicon oxynitride, zirconium oxide, and hafnium oxide, however, the present disclosure should not be limited thereto or thereby. The organic layer may include a phenolic-based polymer, an acrylic-based polymer, an imide-based polymer, an aryl ether-based polymer, an amide-based polymer, a fluorine-based polymer, a p-xylene-based polymer, a vinyl alcohol-based polymer, or blends thereof. However, the material for the organic layer should not be limited thereto or thereby.

The display element layer DP-OL may be disposed on the circuit layer DP-CL. The display element layer DP-OL may include a pixel definition layer PDL and the light emitting element OL. As an example, the light emitting element OL may include an organic light emitting element, an inorganic light emitting element, a quantum dot light emitting element, a micro-LED, or a nano-LED, however, the present disclosure should not be limited thereto or thereby. The light emitting element OL may include various embodiments as long as a light is generated or an amount of the light is controlled according to electrical signals.

The pixel definition layer PDL may be disposed on the second insulating layer INS2 of the circuit layer DP-CL. The pixel definition layer PDL may include a polymer resin. As an example, the pixel definition layer PDL may include a polyacrylate-based resin or a polyimide-based resin. The pixel definition layer PDL may further include an inorganic material in addition to the polymer resin. According to an embodiment, the pixel definition layer PDL may be formed of an inorganic material. As an example, the pixel definition layer PDL may include silicon nitride (SiNₓ), silicon oxide (SiOₓ), or silicon oxynitride (SiOₓN_{y}).

The pixel definition layer PDL may include a light absorbing material. The pixel definition layer PDL may include a black coloring agent. The black coloring agent may include a black pigment or a black dye. The black coloring agent may include a metal material, such as carbon black, chrome, etc., or an oxide thereof. However, the pixel definition layer PDL should not be limited thereto or thereby.

The light emitting element OL may include a first electrode AE, a hole transport region HCL, a light emitting layer EML, an electron transport region ECL, and a second electrode CE, which are sequentially stacked.

The first electrode AE may be disposed on the second insulating layer INS2 of the circuit layer DP-CL. The first electrode AE may be connected to the first connection electrode CNE1 via a contact hole CHa defined through the first insulating layer INS1 and the second insulating layer INS2. As the first electrode AE is connected to the first connection electrode CNE1, the drain area D-A may be connected to the light emitting element OL through the first connection electrode CNE1.

The pixel definition layer PDL may be provided with a light emitting opening PX-OP defined therethrough to extend to and expose at least a portion of the first electrode AE. The portion of the first electrode AE exposed through the light emitting opening PX-OP may correspond to a light-emitting area PXA. The area in which the pixel definition layer PDL is disposed may correspond to a non-light-emitting area NPXA. The non-light-emitting area NPXA may surround the light-emitting area PXA.

The hole transport region HCL may be disposed on the first electrode AE. The hole transport region HCL may include at least one of a hole injection layer, a hole transport layer, and an electron block layer. In addition, the hole transport region HCL may include a plurality of hole transport layers.

The light emitting layer EML may be disposed on the hole transport region HCL. The light emitting layer EML may have a single-layer structure of a single material, a single-layer structure of different materials, or a multi-layer structure of layers including different materials. According to an embodiment, the light emitting layer EML may generate a blue light that is a source light, however, the present disclosure should not be limited thereto or thereby. The display element layer DP-OL may include light emitting elements OL including light emitting layers EML that emit lights having different wavelengths from each other.

The light emitting layer EML may be provided in the form of pattern to be placed in an area corresponding to the light emitting opening PX-OP, however, the present disclosure should not be limited thereto or thereby. According to an embodiment, the light emitting layer EML may be provided as a common layer that overlaps the light-emitting area PXA and the non-light-emitting area NPXA.

The electron transport region ECL may be disposed on the light emitting layer EML. The electron transport region ECL may include at least one of a hole block layer, an electron transport layer, and an electron injection layer, however, the present disclosure should not be limited thereto or thereby.

The hole transport region HCL, the light emitting layer EML, and the electron transport region ECL may be formed by various methods, such as a vacuum deposition method, a spin coating method, a cast method, an LB (Langmuir-Blodgett) method, an inkjet printing method, a laser printing method, an LITI (Laser Induced Thermal Imaging) method, etc.

The second electrode CE may be disposed on the electron transport region ECL. The second electrode CE may be a common electrode. That is, the second electrode CE may be provided as a common layer to overlap the entire area of the light-emitting area PXA and the non-light-emitting area NPXA.

The encapsulation layer TFE may cover the light emitting element OL. The encapsulation layer TFE may encapsulate the display element layer DP-OL. The encapsulation layer TFE may include at least one insulating layer. According to an embodiment, the encapsulation layer TFE may include at least one inorganic layer (hereinafter, referred to as an encapsulation inorganic layer). According to an embodiment, the encapsulation layer TFE may include encapsulation inorganic layers and at least one organic layer (hereinafter, referred to as an encapsulation organic layer) disposed between the encapsulation inorganic layers.

The encapsulation inorganic layer may protect the display element layer DP-OL from moisture and oxygen, and the encapsulation organic layer may protect the display element layer DP-OL from a foreign substance such as dust particles. The encapsulation inorganic layer may include silicon nitride, silicon oxynitride, silicon oxide, titanium oxide, or aluminum oxide, however, it should not be limited thereto or thereby. The encapsulation organic layer may include an acryl-based compound, an epoxy-based compound, or the like. The encapsulation organic layer may include a photopolymerizable organic material, and it should not be particularly limited.

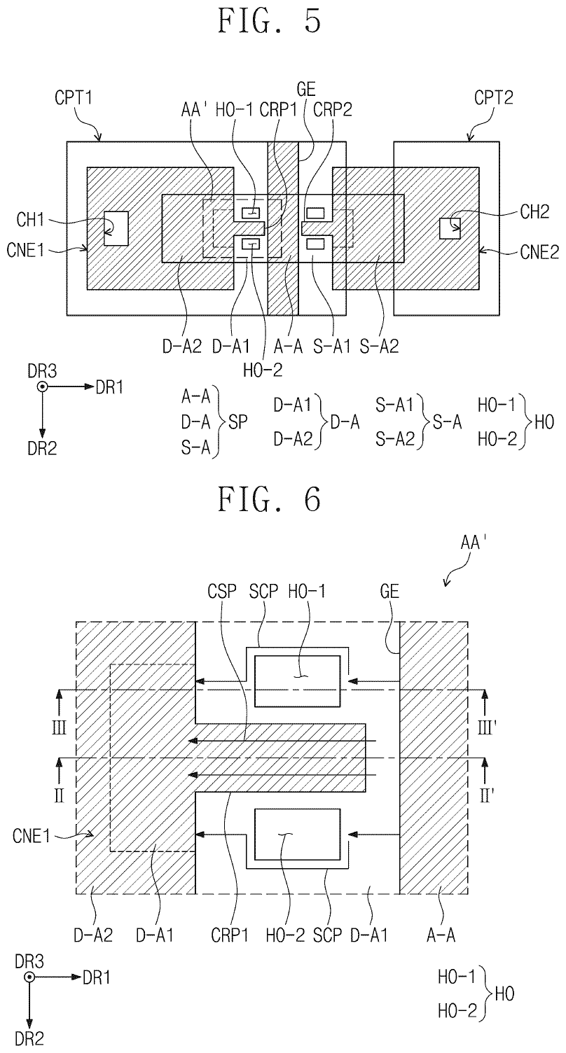

FIG. 5 is a plan view corresponding to the circuit layer of FIG. 4. In detail, FIG. 5 is a plan view showing the first conductive pattern CPT1, the second conductive pattern CPT2, the semiconductor pattern SP, the gate electrode GE, the first connection electrode CNE1, and the second connection electrode CNE2.

Referring to FIG. 5, the first conductive pattern CPT1 and the second conductive pattern CPT2 may be arranged spaced apart from each other when viewed in the plane. The first conductive pattern CPT1 and the second conductive pattern CPT2 may be disposed on the buffer layer BFL (refer to FIG. 4). The first connection electrode CNE1 and the second connection electrode CNE2 may be arranged spaced apart from each other when viewed in the plane. The first connection electrode CNE1 and the second connection electrode CNE2 may be disposed on the gate insulating pattern GI (refer to FIG. 4). The first connection electrode CNE1 may be electrically connected to the first conductive pattern CPT1 via the first contact hole CH1. The second connection electrode CNE2 may be electrically connected to the second conductive pattern CPT2 via the second contact hole CH2.

The semiconductor pattern SP may overlap the first connection electrode CNE1, the second connection electrode CNE2, and the gate electrode GE. The semiconductor pattern SP may overlap the first conductive pattern CPT1 and the second conductive pattern CPT2. However, it should not be limited thereto or thereby, and the semiconductor pattern SP may have a variety of shapes. As an example, the semiconductor pattern SP may not overlap the second conductive pattern CPT2.

The semiconductor pattern SP may include the semiconductor material, such as polycrystalline silicon, crystalline silicon, or metal oxide. The semiconductor pattern SP may include the active area A-A, the source area S-A, and the drain area D-A. The semiconductor pattern SP may have different electrical properties depending on whether it is doped or not or whether the metal oxide is reduced or not. The source area S-A and the drain area D-A of the semiconductor pattern SP, which have the relatively high conductivity, may serve as the electrode or the signal line. The non-doped portion, the portion doped with low doping concentration, or the non-reduced portion of the semiconductor pattern SP may correspond to the active area A-A with the relatively low conductivity. The active area A-A of the semiconductor pattern SP may overlap the gate electrode GE of the semiconductor pattern SP. The active area A-A may have the relatively low conductivity than the source area S-A and the drain area D-A.

The at least one hole HO may be defined through the semiconductor pattern SP of the transistor TR (refer to FIG. 4). The hole HO may be disposed adjacent to one of the source area S-A and the drain area D-A. The hole HO may be formed during the etching process of forming the connection electrodes CNE1 and CNE2 and the gate electrode GE. The hole HO may be defined in plural. FIG. 5 shows the structure in which the holes HO are formed spaced apart from each other. Among the holes HO, the at least one hole may be surrounded by the source area S-A, and the other hole may be surrounded by the drain area D-A. First holes HO-1 may be respectively defined above a first protrusion pattern CRP1 and a second protrusion pattern CRP2, which are described later, when viewed in the plane. Second holes HO-2 may be respectively defined under the first protrusion pattern CRP1 and the second protrusion pattern CRP2, which are described later, when viewed in the plane.

The protrusion patterns CRP1 and CRP2 may protrude (extend) from the connection electrodes CNE1 and CNE2 to the active area A-A, respectively. The protrusion patterns CRP1 and CRP2 may electrically connect the active area A-A and the connection electrodes CNE1 and CNE2. As the protrusion patterns CRP1 and CRP2 electrically connect the active area A-A and the connection electrodes CNE1 and CNE2, a resistance may be reduced and a current may smoothly flow when the current flows from the active area A-A to the source area S-A and the drain area D-A. This will be described in detail later.

The first connection electrode CNE1 may include the first protrusion pattern CRP1 protruded in the first direction DR1. The first protrusion pattern CRP1 may protrude from the first drain area D-A1 to the active area A-A, i.e., towards to be adjacent to but not overlapping the active area A-A. The first protrusion pattern CRP1 may include the same material as the first connection electrode CNE1 having the high conductivity. The first protrusion pattern CRP1 may overlap the drain area D-A and may not overlap the active area A-A.

The first protrusion pattern CRP1 may be disposed between the first hole HO-1 and the second hole HO-2. The first hole HO-1 may be defined above the first protrusion pattern CRP1 when viewed in the plane, and the second hole HO-2 may be defined under the first protrusion pattern CRP1 when viewed in the plane. The first protrusion pattern CRP1 may not overlap the first hole HO-1 and the second hole HO-2. However, the shapes and locations of the first protrusion pattern CRP1, the first hole HO-1, and the second hole HO-2 should not be limited thereto or thereby and may be changed as needed. As an example, one hole may be formed to surround the first protrusion pattern CRP1.

The second connection electrode CNE2 may include the second protrusion pattern CRP2 protruded in a direction opposite to the first direction DR1. The second protrusion pattern CRP2 may protrude from the first source area S-A1 to the active area A-A, i.e., towards to be adjacent to but not overlapping the active area A-A. The second protrusion pattern CRP2 may include the same material as the second connection electrode CNE2 having the high conductivity. The second protrusion pattern CRP2 may overlap the source area S-A and may not overlap the active area A-A.

The second protrusion pattern CRP2 may be disposed between the first hole HO-1 and the second hole HO-2. The second protrusion pattern CRP2 may not overlap the first hole HO-1 and the second hole HO-2. The first hole HO-1 may be defined above the second protrusion pattern CRP2 when viewed in the plane, and the second hole HO-2 may be defined under the second protrusion pattern CRP2 when viewed in the plane. However, the shapes and locations of the second protrusion pattern CRP2, the first hole HO-1, and the second hole HO-2 should not be limited thereto or thereby and may be changed as needed.

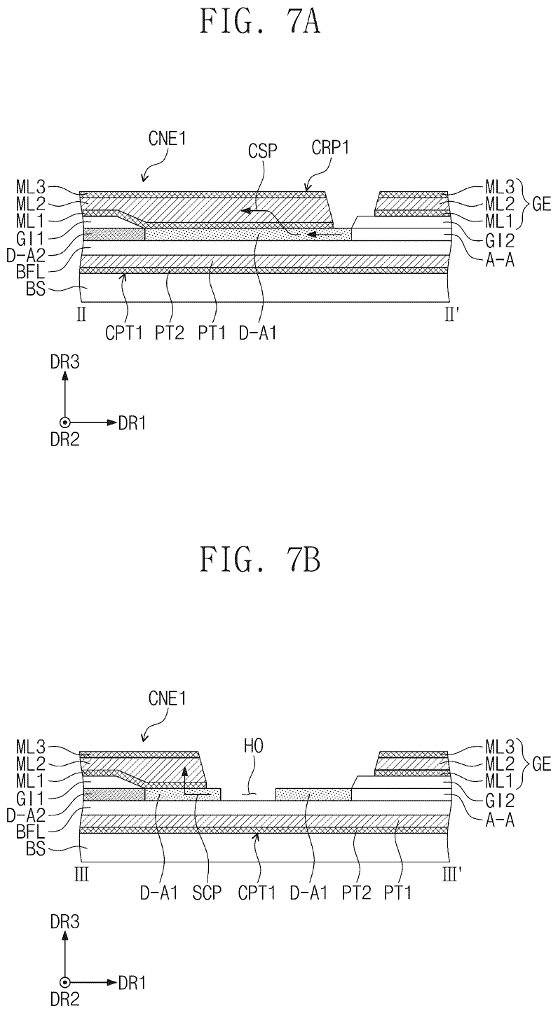

FIG. 6 is an enlarged plan view of an area AA′ of FIG. 5. Hereinafter, in FIG. 6, the same reference numerals denote the same elements in FIGS. 1 to 5, and thus, detailed descriptions of the same elements will be omitted. In addition, descriptions on the first protrusion pattern CRP1 may be applied to the second protrusion pattern CRP2.

Referring to FIG. 6, the first protrusion pattern CRP1 may protrude from the first drain area D-A1 to the active area A-A along the first direction DR1. In a case where there is no first protrusion pattern CRP1, a path of a current that flows from the active area A-A to the first drain area D-A1 may be limited to a surrounding current path SCP. Since the surrounding current path SCP is required to avoid the hole HO and to enter the first drain area D-A1, a current path may become narrow, and thus, a resistance may increase. In the present embodiment, descriptions are made based on the premise that the surrounding current path SCP flows in a direction from the active area A-A to the drain area D-A, however, the surrounding current path SCP may flow in a direction opposite to the above-mentioned direction. The surrounding current path SCP described hereinafter may flow in both directions as described above.

In the case where the first protrusion pattern CRP1 is disposed between the first hole HO-1 and the second hole HO-2, an additional current path CSP may be added to the path of the current flowing from the active area A-A to the first drain area D-A1 via the first protrusion pattern CRP1. In the present embodiment, descriptions are made based on the premise that the additional current path CSP flows in a direction from the active area A-A to the drain area D-A, however, the additional current path CSP may flow in a direction opposite to the above-mentioned direction. The additional current path CSP described hereinafter may flow in both directions as described above. As the first protrusion pattern CRP1 includes the same material as the first connection electrode CNE1, the first protrusion pattern CRP1 has high conductivity, and the current may flow from the active area A-A to the first drain area D-A1 via the first protrusion pattern CRP1. Accordingly, the current path may become wider compared with the case where the first protrusion pattern CRP1 is not provided, and thus, the current resistance may be reduced.

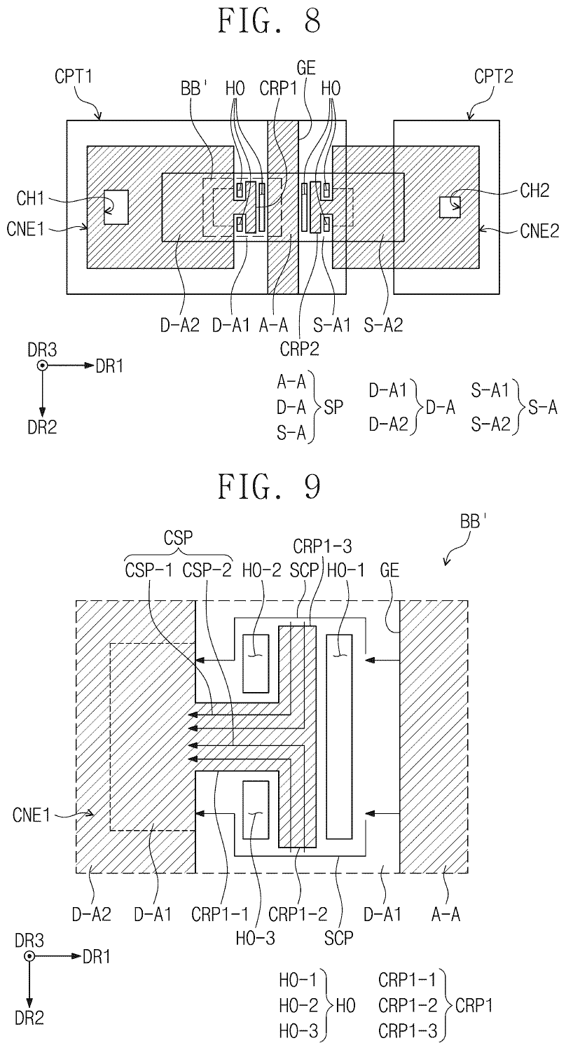

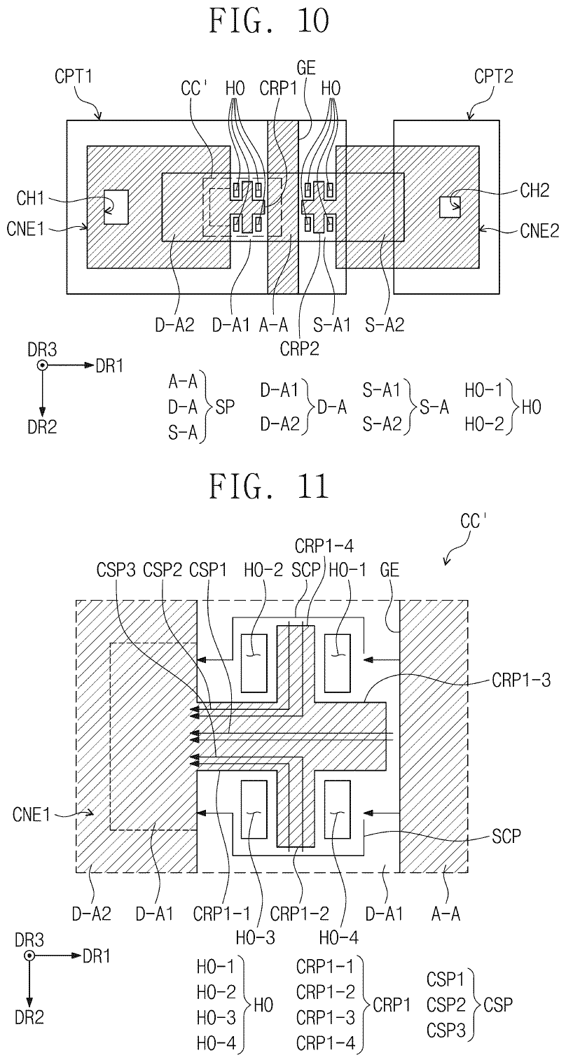

FIG. 7A is a cross-sectional view taken along a line II-II′ of FIG. 6. In FIG. 7A, the same reference numerals denote the same elements in FIGS. 1 to 6, and thus, detailed descriptions of the same elements will be omitted.

Referring to FIG. 7A, the first gate insulating pattern GI1 may cover the second drain area D-A2. The first drain area D-Al may be directly in contact with and electrically connected to the first protrusion pattern CRP1. The first protrusion pattern CRP1 may include the first, second, and third conductive layers ML1, ML2, and ML3 that include the same material as the first connection electrode CNE1. The first protrusion pattern CRP1 may include the same material as the gate electrode GE. The first protrusion pattern CRP1, the first connection electrode CNE1, and the gate electrode GE may be formed through the same process.

The active area A-A may be electrically connected to the first drain area D-A1 and the first protrusion pattern CRP1. Accordingly, the additional current path CSP may be formed from the active area A-A to the first connection electrode CNE1 through the first drain area D-A1 and the first protrusion pattern CRP1. The additional current path CSP may have a current path wider than the surrounding current path SCP described later with reference to FIG. 7B, and thus, an overall electrical resistance may be reduced.

FIG. 7B is a cross-sectional view taken along a line III-III′ of FIG. 6. In FIG. 7B, the same reference numerals denote the same elements in FIGS. 1 to 6 and 7A, and thus, detailed descriptions of the same elements will be omitted.

Referring to FIGS. 6 and 7B, the current path may become narrow due to the hole HO overlapping the first drain area D-A1. That is, the current that start to flow from the active area A-A may avoid the holes HO and may flow into the first drain area D-A1. Since the current path avoids the holes HO, the current path may become narrow, and the resistance may increase when the current flows through the surrounding current path SCP. The resistance of the surrounding current path SCP may increase as the size of the holes HO increases in a process of forming the circuit layer. In this case, the resistance may be reduced by the additional current path CSP (refer to FIG. 7A).

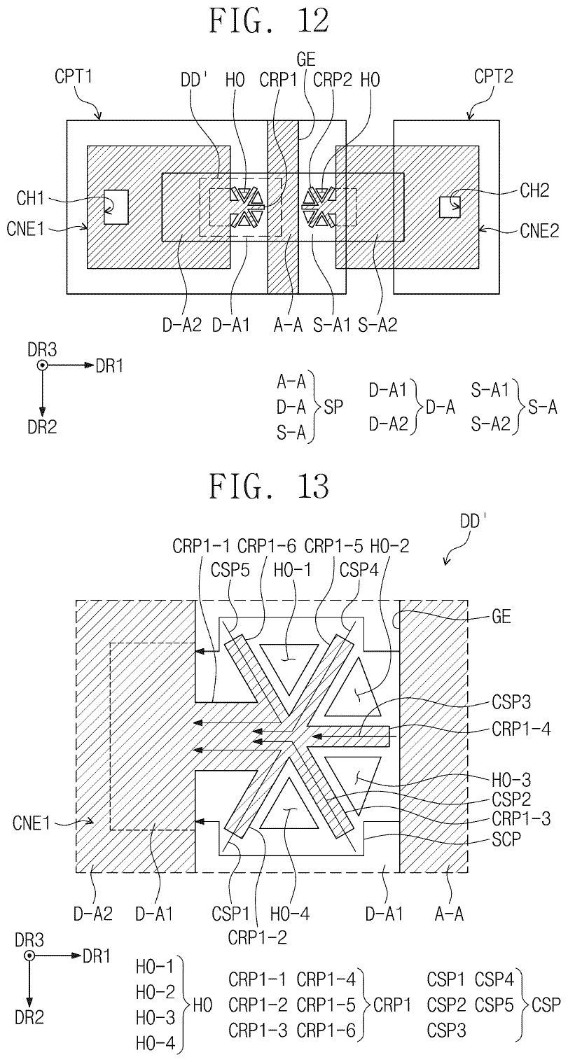

FIG. 8 is a plan view corresponding to the circuit layer of FIG. 4 according to an embodiment of the present disclosure. In detail, FIG. 8 is a plan view illustrating a first conductive pattern CPT1, a second conductive pattern CPT2, a semiconductor pattern SP, a gate electrode GE, a first connection electrode CNE1, and a second connection electrode CNE2.

The circuit layer of FIG. 8 has substantially the same configuration as the circuit layer of FIG. 5 except a first protrusion pattern CRP1, a second protrusion pattern CRP2, and holes HO.

The first protrusion pattern CRP1 may include a portion protruded in the first direction DR1 and a portion extending in a direction parallel to the second direction DR2 from the portion protruded in the first direction DR1. Similarly, the second protrusion pattern CRP2 may include a portion protruded in the direction opposite to the first direction DR1 and a portion extending in the direction parallel to the second direction DR2 from the portion protruded in the direction opposite to the first direction DR1. The holes HO may be defined adjacent to the first protrusion pattern CRP1 and the second protrusion pattern CRP2. As shown in FIG. 8, three holes HO may be defined around the first protrusion pattern CRP1. Three holes HO may be defined around the second protrusion pattern CRP2. The shape of the first protrusion pattern CRP1 and the second protrusion pattern CRP2 should not be limited thereto or thereby and may be changed as needed.

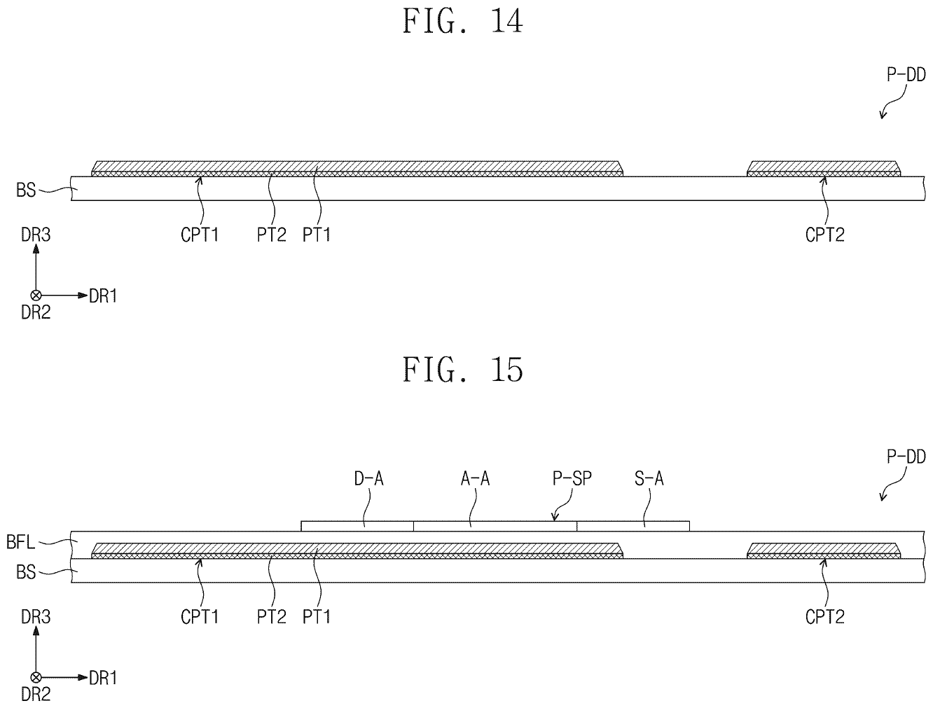

FIG. 9 is an enlarged plan view of an area BB′ of FIG. 8. Hereinafter, in FIG. 9, the same reference numerals denote the same elements described above, and thus, detailed descriptions of the same elements will be omitted. In addition, descriptions on the first protrusion pattern CRP1 may be applied to the second protrusion pattern CRP2.

Referring to FIG. 9, the first protrusion pattern CRP1 may protrude from a first drain area D-A1 to an active area A-A along the first direction DR1. The first protrusion pattern CRP1 may include a first-first protrusion pattern CRP1-1 extending in the first direction DR1, a first-second protrusion pattern CRP1-2 extending in the second direction DR2, and a first-third protrusion pattern CRP1-3 extending in a direction opposite to the second direction DR2. A second hole HO-2 may be defined above the first-first protrusion pattern CRP1-1 when viewed in the plane, and a third hole HO-3 may be defined under the first-first protrusion pattern CRP1-1 when viewed in the plane. A first hole HO-1 may be defined at a right side of the first-second protrusion pattern CRP1-2 and the first-third protrusion pattern CRP1-3 and may extend in the second direction DR2.

Since the first protrusion pattern CRP1 includes various protrusion portions, various current paths may be formed when a current flows from the active area A-A to the first drain area D-A1.

A current flowing through a surrounding current path SCP may flow from the active area A-A to the first drain area D-A1 while avoiding the holes HO. A current flowing through an additional current path CSP may include a first additional current path CSP-1 and a second additional current path CSP-2. The current flowing through the additional current path CSP may pass through the first protrusion pattern CRP1 and may flow into the first drain area D-A1.

The current that starts to flow from the active area A-A may flow into an upper end of the first-third protrusion pattern CRP1-3 through the first additional current path CSP-1. The current that flows to the upper end of the first-third protrusion pattern CRP1-3 through the first additional current path CSP-1 may travel to the second direction DR2 via the first-third protrusion pattern CRP1-3 and then may travel to the direction opposite to the first direction DR1 via the first-first protrusion pattern CRP1-1. As described above, the current flowing through the first additional current path CSP-1 may flow into the first drain area D-A1 via the first-third protrusion pattern CRP1-3 and the first-first protrusion pattern CRP1-1.

The current that starts to flow from the active area A-A may flow into a lower end of the first-second protrusion pattern CRP1-2 through the second additional current path CSP-2. The current that flows to the lower end of the first-second protrusion pattern CRP1-2 through the second additional current path CSP-2 may travel to the direction opposite to the second direction DR2 through the first-second protrusion pattern CRP1-2 and then may travel to the direction opposite to the first direction DR1 through the first-first protrusion pattern CRP1-1. As described above, the current flowing through the second additional current path CSP-2 may flow into the first drain area D-A1 through the first-second protrusion pattern CRP1-2 and the first-first protrusion pattern CRP1-1. As described above, as the first protrusion pattern CRP1 includes the first-first protrusion pattern CRP1-1, the first-second protrusion pattern CRP1-2, and the first-third protrusion pattern CRP1-3, additional current paths CSP-1 and CSP-2 may increase, and the resistance may be reduced.

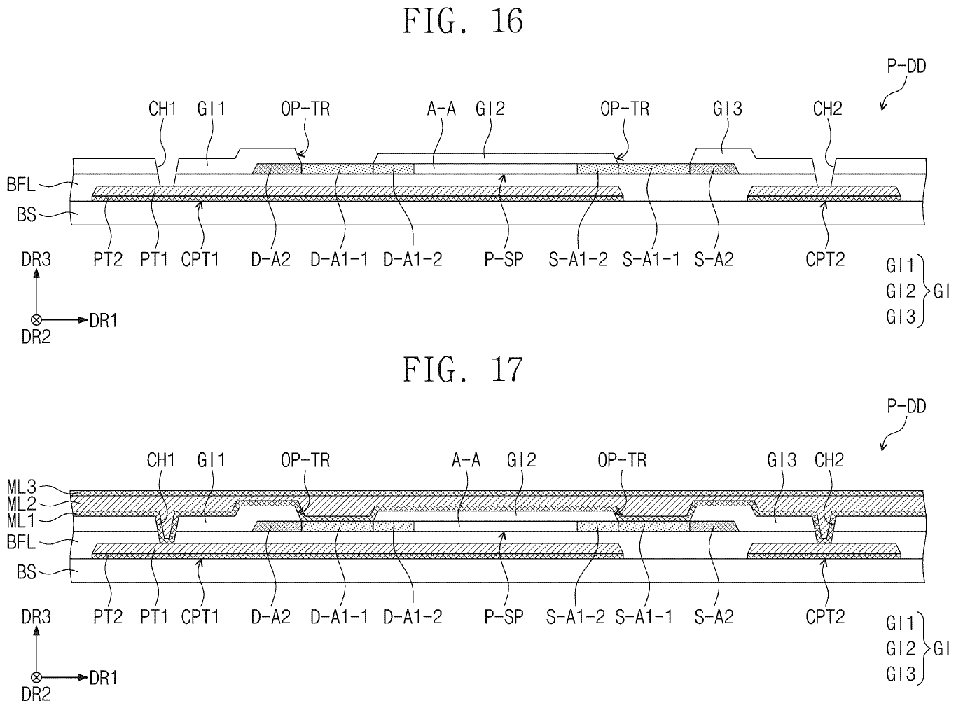

FIG. 10 is a plan view corresponding to of the circuit layer of FIG. 4 according to an embodiment of the present disclosure. In detail, FIG. 10 is a plan view illustrating a first conductive pattern CPT1, a second conductive pattern CPT2, a semiconductor pattern SP, a gate electrode GE, a first connection electrode CNE1, and a second connection electrode CNE2.

The circuit layer of FIG. 10 has substantially the same configuration as the circuit layer of FIG. 5 except the first protrusion pattern CRP1, the second protrusion pattern CRP2, and the holes HO.

The first protrusion pattern CRP1 may include a portion protruded in the first direction DR1 and a portion extending in the direction parallel to the second direction DR2 from the portion protruded in the first direction DR1. Similarly, the second protrusion pattern CRP2 may include a portion protruded in the direction opposite to the first direction DR1 and a portion extending in the direction parallel to the second direction DR2 from the portion protruded in the direction opposite to the first direction DR1. The holes HO may be disposed adjacent to the first protrusion pattern CRP1 and the second protrusion pattern CRP2. As shown in FIG. 10, four holes HO may be disposed around the first protrusion pattern CRP1, and four holes HO may be disposed around the second protrusion pattern CRP2. The shape of the first protrusion pattern CRP1 and the second protrusion pattern CRP2 should not be limited thereto or thereby and may be changed as needed.

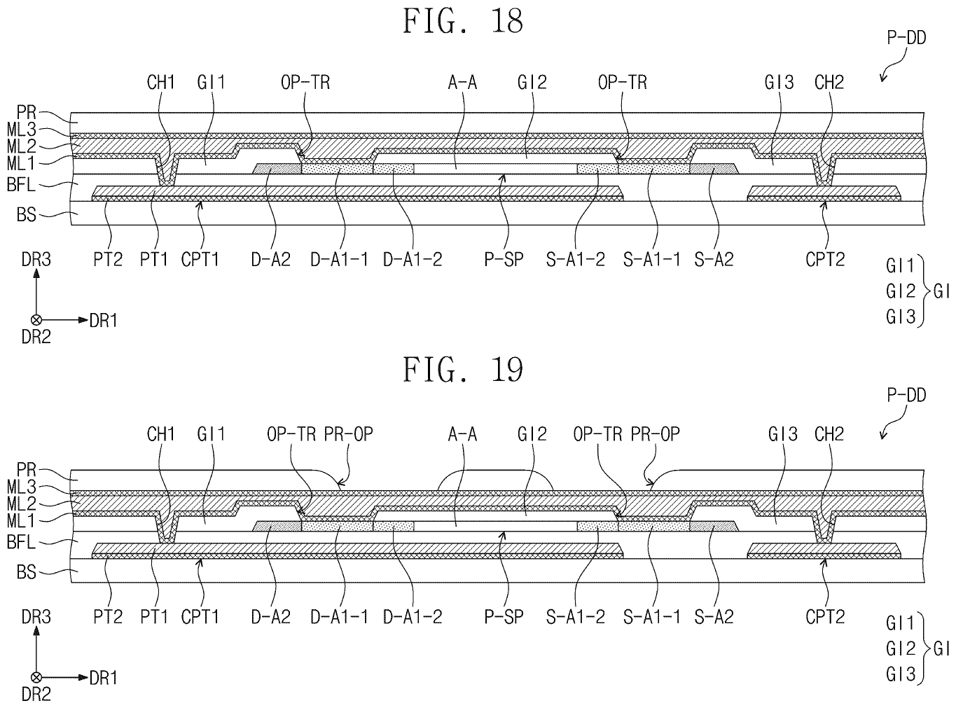

FIG. 11 is an enlarged plan view of an area CC′ of FIG. 10. Hereinafter, in FIG. 11, the same reference numerals denote the same elements in FIG. 10, and thus, detailed descriptions of the same elements will be omitted. In addition, descriptions on the first protrusion pattern CRP1 may be applied to the second protrusion pattern CRP2.

Referring to FIG. 11, the first protrusion pattern CRP1 may protrude from a first drain area D-A1 to an active area A-A along the first direction DR1. The first protrusion pattern CRP1 may include a first-first protrusion pattern CRP1-1 extending in the first direction DR1, a first-second protrusion pattern CRP1-2 extending in the second direction DR2, a first-third protrusion pattern CRP1-3 extending in the first direction DR1, and a first-fourth protrusion pattern CRP1-4 extending in the direction opposite to the second direction DR2. A second hole HO-2 may be defined above the first-first protrusion pattern CRP1-1 when viewed in the plane, and a third hole HO-3 may be defined under the first-first protrusion pattern CRP1-1 when viewed in the plane. A first hole HO-1 may be defined above the first-third protrusion pattern CRP1-3 when viewed in the plane, and a fourth hole HO-4 may be defined under the first-third protrusion pattern CRP1-3 when viewed in the plane. Each of the first, second, third, and fourth protrusion patterns CRP1-1, CRP1-2, CRP1-3, and CRP1-4 may be disposed between two holes of the first, second, third, and fourth holes HO-1, HO-2, HO-3, and HO-4.

Since the first protrusion pattern CRP1 includes various protrusion portions, various current paths may be formed when a current flows from the active area A-A to the first drain area D-A1.

A current flowing through the surrounding current path SCP may flow into the first drain area D-A1 from the active area A-A while avoiding the holes HO. A current flowing through an additional current path CSP may include a first additional current path CSP1, a second additional current path CSP2, and a third additional current path CSP3. The current flowing through additional current path CSP may pass through the first protrusion pattern CRP1 and may flow into the first drain area D-A1.

The current that starts to flow from the active area A-A may travel to the first drain area D-A1 in the direction opposite to the first direction DR1 via the first-third protrusion pattern CRP1-3 and the first-first protrusion pattern CRP1-1 through the first additional current path CSP1. The second additional current path CSP2 may flow into an upper end of the first-fourth protrusion pattern CRP1-4, may travel to the second direction DR2 through the first-fourth protrusion pattern CRP1-4, and then may travel to the direction opposite to the first direction DR1 through the first-first protrusion pattern CRP1-1. The third additional current path CSP3 may flow into a lower end of the first-second protrusion pattern CRP1-2, may travel to the direction opposite to the second direction DR2 through the first-second protrusion pattern CRP1-2, and may travel to the direction opposite to the first direction DR1 through the first-first protrusion pattern CRP1-1.

As described above, the first additional current path CSP1 may flow into the first drain area D-A1 through the first-third protrusion pattern CRP1-3 and the first-first protrusion pattern CRP1-1. The second additional current path CSP2 may flow into the first drain area D-A1 through the first-fourth protrusion pattern CRP1-4 and the first-first protrusion pattern CRP1-1. The third additional current path CSP3 may flow into the first drain area D-A1 through the first-second protrusion pattern CRP1-2 and the first-first protrusion pattern CRP1-1. As described above, as the first protrusion pattern CRP1 includes the first-first protrusion pattern CRP1-1, the first-second protrusion pattern CRP1-2, the first-third protrusion pattern CRP1-3, and the first-fourth protrusion pattern CRP1-4, additional current paths CSP1, CSP2, and CSP3 may increase, and the resistance may be reduced.

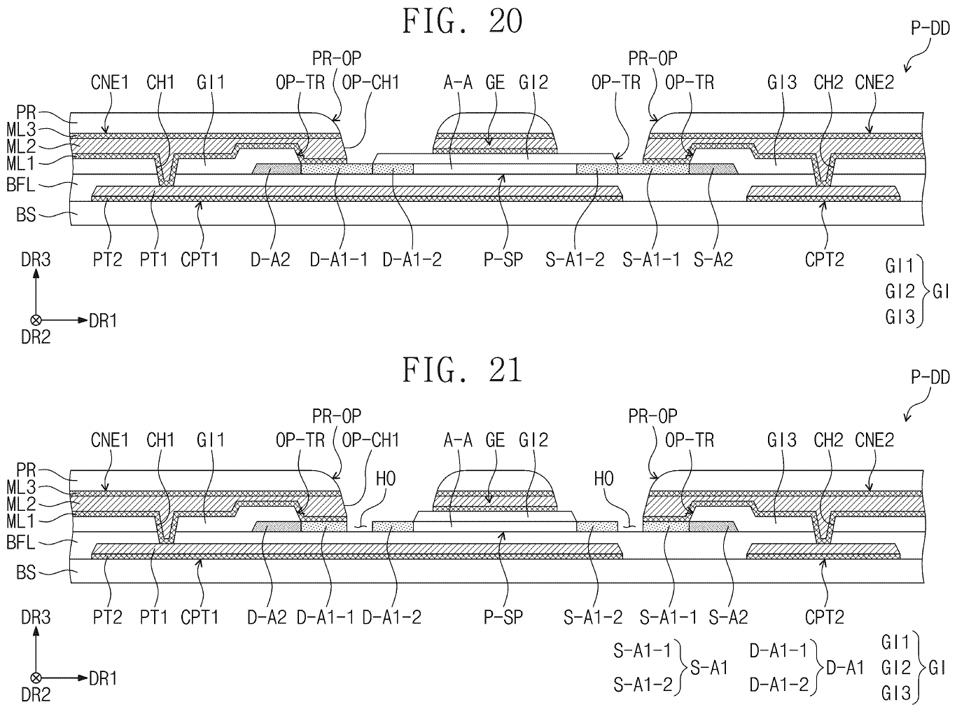

FIG. 12 is a plan view corresponding to the circuit layer of FIG. 4 according to an embodiment of the present disclosure. In detail, FIG. 12 is a plan view illustrating a first conductive pattern CPT1, a second conductive pattern CPT2, a semiconductor pattern SP, a gate electrode GE, a first connection electrode CNE1, and a second connection electrode CNE2.

The circuit layer of FIG. 12 has substantially the same configuration as the circuit layer of FIG. 5 except a first protrusion pattern CRP1, a second protrusion pattern CRP2, and holes HO.

The first protrusion pattern CRP1 may be provided in plural and may protrude radially outward around a center point. Similarly, the second protrusion pattern CRP2 may be provided in plural and may protrude radially outward around a center point. The holes HO may be disposed adjacent to the first protrusion patterns CRP1 and the second protrusion patterns CRP2. As shown in FIG. 12, four holes HO may be disposed around the first protrusion patterns CRP1, and four holes HO may be disposed around the second protrusion patterns CRP2. The shape of the first protrusion pattern CRP1 and the second protrusion pattern CRP2 should not be limited thereto or thereby and may be changed as needed.

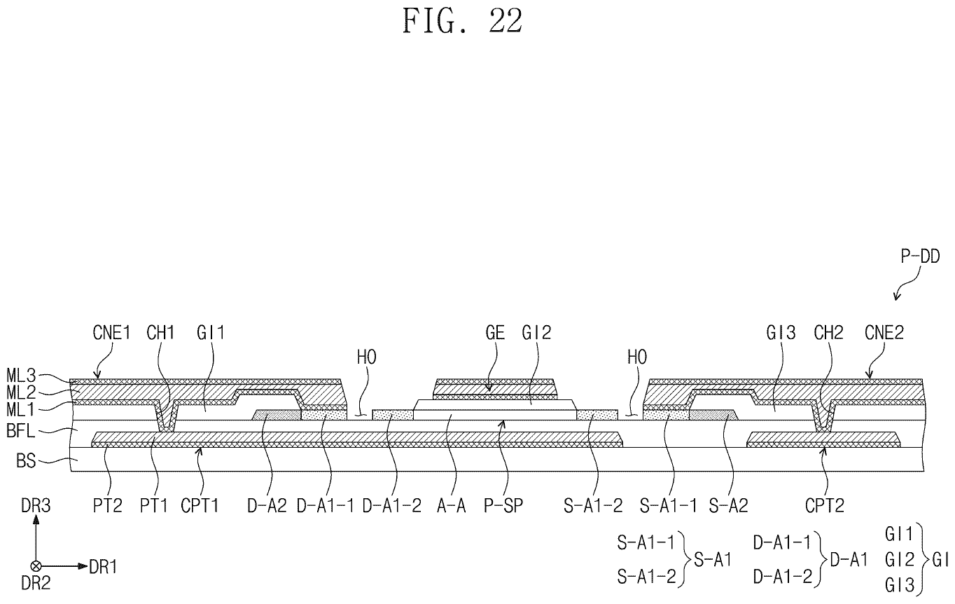

FIG. 13 is an enlarged plan view of an area DD′ of FIG. 12. Hereinafter, in FIG. 13, the same reference numerals denote the same elements in FIG. 12, and thus, detailed descriptions of the same elements will be omitted. In addition, descriptions on the first protrusion pattern CRP1 may be applied to the second protrusion pattern CRP2.

Referring to FIG. 13, the first protrusion pattern CRP1 may protrude from a first drain area D-A1 to an active area A-A. The first protrusion pattern CRP1 may include a first-first protrusion pattern CRP1-1, a first-second protrusion pattern CRP1-2, a first-third protrusion pattern CRP1-3, a first-fourth protrusion pattern CRP1-4, a first-fifth protrusion pattern CRP1-5, and a first-sixth protrusion pattern CRP1-6, which protrude radially around the center point. A first hole HO-1 may be disposed between the first-fifth protrusion pattern CRP1-5 and the first-sixth protrusion pattern CRP1-6. A second hole HO-2 may be disposed between the first-fourth protrusion pattern CRP1-4 and the first-fifth protrusion pattern CRP1-5. A third hole HO-3 may be disposed between the first-third protrusion pattern CRP1-3 and the first-fourth protrusion pattern CRP1-4. A fourth hole HO-4 may be disposed between the first-second protrusion pattern CRP1-2 and the first-third protrusion pattern CRP1-3.

Each of the first, second, third, fourth, firth, and sixth protrusion patterns CRP1-1, CRP1-2, CRP1-3, CRP1-4, CRP1-5, and CRP1-6 may be disposed adjacent to at least one hole of the first, second, third, and fourth holes HO-1, HO-2, HO-3, and HO-4.

Since the first protrusion pattern CRP1 includes various protrusion portions, various current paths may be formed when a current flows from the active area A-A to the first drain area D-A1.

A current flowing through a surrounding current path SCP may flow into the first drain area D-A1 from the active area A-A while avoiding the holes HO. A current flowing through an additional current path CSP may include a first additional current path CSP1, a second additional current path CSP2, a third additional current path CSP3, a fourth additional current path CSP4, and a fifth additional current path CSP5. The current flowing through the additional current path CSP may pass through the first protrusion pattern CRP1 and may flow into the first drain area D-A1.

The first additional current path CSP1 may travel to the first drain area D-A1 in the direction opposite to the first direction DR1 along the first-first protrusion pattern CRP1-1 after passing through the first-second protrusion pattern CRP1-2. The second additional current path CSP2 may travel to the direction opposite to the first direction DR1 along the first-first protrusion pattern CRP1-1 after passing through the first-third protrusion pattern CRP1-3. The third additional current path CSP3 may travel to the direction opposite to the first direction DR1 along the first-fourth protrusion pattern CRP1-4 and the first-first protrusion pattern CRP1-1. The fourth additional current path CSP4 may travel to the direction opposite to the first direction DR1 along the first-first protrusion pattern CRP1-1 after passing through the first-fifth protrusion pattern CRP1-5. The fifth additional current path CSP5 may travel to the direction opposite to the first direction DR1 along the first-first protrusion pattern CRP1-1 after passing through the first-sixth protrusion pattern CRP1-6.

As described above, as the first protrusion pattern CRP1 includes the first-first protrusion pattern CRP1-1, the first-second protrusion pattern CRP1-2, the first-third protrusion pattern CRP1-3, the first-fourth protrusion pattern CRP1-4, the first-fifth protrusion pattern CRP1-5, and the first-sixth protrusion pattern CRP1-6, additional current paths CSP1, CSP2, CSP3, CSP4, and CSP5 may increase, and the resistance may be reduced.

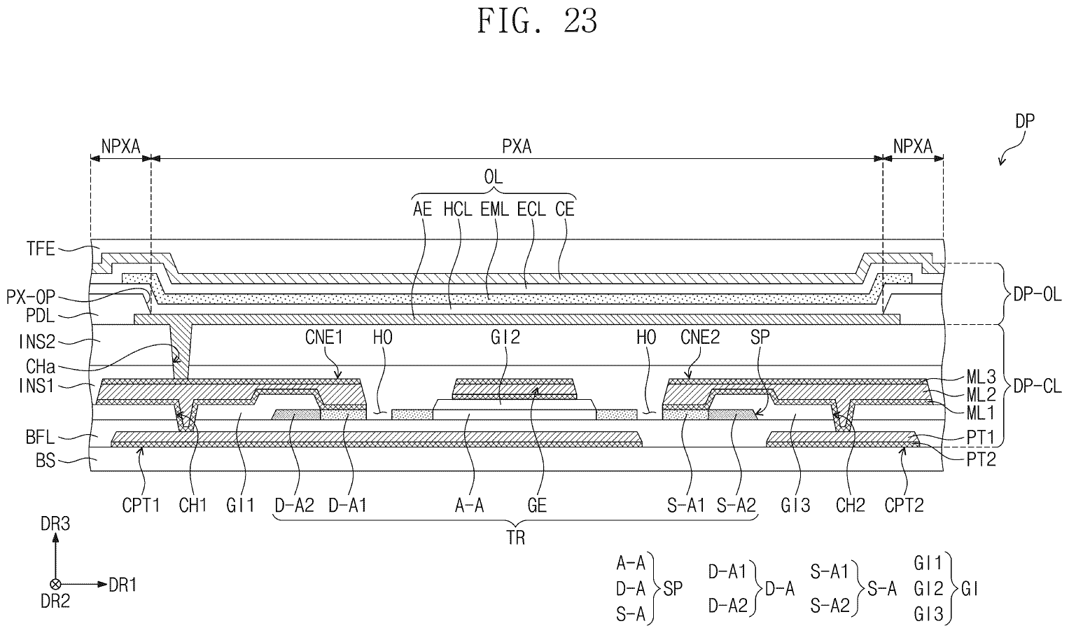

FIGS. 14 to 23 are cross-sectional views illustrating a method of manufacturing the electronic device according to an embodiment of the present disclosure. In FIGS. 14 to 23, the same reference numerals denote the same elements in FIGS. 1 to 13, and thus, detailed descriptions of the same elements will be omitted.

Referring to FIG. 14, a preliminary electronic device P-DD that includes the base substrate BS, the first conductive pattern CPT1 disposed on the base substrate BS, and the second conductive pattern CPT2 spaced apart from the first conductive pattern CPT1 when viewed in the plane may be prepared. Each of the first conductive pattern CPT1 and the second conductive pattern CPT2 may include the first pattern layer PT1 and the second pattern layer PT2, which are stacked in the thickness direction.

Referring to FIG. 15, the buffer layer BFL may be formed to cover the first conductive pattern CPT1 and the second conductive pattern CPT2. A preliminary semiconductor pattern P-SP that includes the source area S-A, the active area A-A, and the drain area D-A may be formed on the buffer layer BFL.

Referring to FIG. 16, the gate insulating pattern GI may be formed on the preliminary semiconductor pattern P-SP. The first contact hole CH1 may be formed through the gate insulating pattern GI to expose the upper surface of the first conductive pattern CPT1. The second contact hole CH2 may be formed through the gate insulating pattern GI to expose the upper surface of the second conductive pattern CPT2. A first opening OP-TR may be formed through the gate insulating pattern GI to expose a first portion of the preliminary semiconductor pattern P-SP. The gate insulating pattern GI may include the first, second, and third gate insulating patterns GI1, GI2, and GI3 spaced apart from each other. The first gate insulating pattern GI1 may cover the second drain area D-A2. The second gate insulating pattern GI2 may cover a first-second drain area D-A1-2, the active area A-A, and a first-second source area S-A1-2. The third gate insulating pattern GI3 may cover the second source area S-A2.

When the first opening OP-TR is formed, the first portion of the preliminary semiconductor pattern P-SP, which is exposed through the first opening OP-TR, may be doped. In this case, a first-first drain area D-A1-1 and a first-first source area S-A1-1, which are exposed, may be doped.

Referring to FIG. 17, the conductive layers ML1, ML2, and ML3 may be formed on the gate insulating pattern GI. The conductive layers ML1, ML2, and ML3 may include the first, second, and third conductive layers ML1, ML2, and ML3. The conductive layers ML1, ML2, and ML3 may cover the preliminary semiconductor pattern P-SP. The conductive layers ML1, ML2, and ML3 may be filled in the first contact hole CH1, the second contact hole CH2, and the first opening OP-TR.

Referring to FIGS. 18 and 19, a photoresist layer PR through which a photo opening PR-OP is defined may be formed on the conductive layers ML1, ML2, and ML3. The photoresist layer PR may be provided to etch a portion corresponding to the photo opening PR-OP.

Referring to FIG. 20, a second opening OP-CHI may be formed through the conductive layers ML1, ML2, and ML3 to correspond to the photo opening PR-OP. A portion of the first portion of the preliminary semiconductor pattern P-SP may be exposed through the second opening OP-CH1. That is, a portion of each of the first-first drain area D-A1-1 and the first-first source area S-A1-1 may be exposed. The conductive layers ML1, ML2, and ML3 may be divided into the gate electrode GE, the first connection electrode CNE1, and the second connection electrode CNE2 by the second opening OP-CH1. The gate electrode GE may correspond to the active area A-A.

In this case, the protrusion patterns CRP1 and CRP2 (refer to FIG. 5) may be formed together with the gate electrode GE, the first connection electrode CNE1, and the second connection electrode CNE2. The protrusion patterns CRP1 and CRP2 (refer to FIG. 5) may correspond to the portion of the connection electrodes CNE1 and CNE2 and may protrude to the active area A-A. That is, the first connection electrode CNE1, the second connection electrode CNE2, the gate electrode GE, and the protrusion patterns CRP1 and CRP2 (refer to FIG. 5) may be formed by etching the conductive layers ML1, ML2, and ML3. The protrusion patterns CRP1 and CRP2 (refer to FIG. 5) are described previously, and thus, detail thereof will be omitted.

Referring to FIG. 21, a portion of the second gate insulating pattern GI2, which corresponds to the second opening OP-CH1, may be etched. In this case, the first-second drain area D-A1-2 and the first-second source area S-A1-2, which are covered by the second gate insulating pattern GI2, may be doped.

In addition, the hole HO may be formed through the preliminary semiconductor pattern P-SP and may be disposed adjacent to one of the source area S-A and the drain area D-A. The hole HO may be provided in plural, and each of the holes HO may overlap the first drain area D-A1 or the first source area S-A1. The hole HO may penetrate the semiconductor pattern SP. The portion of the upper surface of the buffer layer BFL may be exposed through the hole HO.

Referring to FIG. 22, the photoresist layer PR that serves as a mask may be removed.

Referring to FIG. 23, the insulating layers INS1 and INS2, the display element layer DP-OL, and the encapsulation layer TFE may be formed on the preliminary electronic device P-DD of FIG. 22 to manufacture the display panel DP.

Although the embodiments of the present disclosure have been described, it is understood that the present disclosure should not be limited to these embodiments but various changes and modifications can be made by one ordinary skilled in the art within the spirit and scope of the present disclosure as hereinafter claimed. Therefore, the disclosed subject matter should not be limited to any single embodiment described herein, and the scope of the present inventive concept shall be determined according to the attached claims.

What is claimed is:

1. An electronic device comprising:
a base substrate;
a transistor disposed on the base substrate and comprising a semiconductor pattern comprising a source area, an active area, and a drain area and a gate electrode;
a gate insulating pattern disposed on the semiconductor pattern; and
a connection electrode disposed on the gate insulating pattern and electrically connected to the semiconductor pattern, wherein a first hole extends through the transistor and is disposed adjacent to one of the source area and the drain area, the connection electrode is disposed on a same layer as the gate electrode, and the connection electrode comprises a protrusion pattern protruded towards the active area when viewed in a plane.

2. The electronic device of claim 1, further comprising a plurality of first holes comprising the first hole, and the protrusion pattern is disposed between the first holes.

3. The electronic device of claim 1, wherein the protrusion pattern comprises a first protrusion pattern that extends in a direction parallel to a first direction from one of the source area and the drain area towards the active area.

4. The electronic device of claim 3, wherein the protrusion pattern comprises a second protrusion pattern that extends from the first protrusion pattern in a direction parallel to a second direction intersecting the first direction.

5. The electronic device of claim 1, wherein the connection electrode is electrically connected to the source area or the drain area.

6. The electronic device of claim 1, wherein the protrusion pattern is electrically connected to the active area.

7. The electronic device of claim 1, wherein the protrusion pattern is disposed directly on the source area or the drain area.

8. The electronic device of claim 1, wherein the first hole does not overlap the protrusion pattern.

9. The electronic device of claim 1, further comprising a plurality of protrusion patterns comprising the protrusion pattern, and the protrusion patterns protrude radially around a center point.

10. The electronic device of claim 1, further comprising a plurality of connection electrodes comprising the connection electrode, and each of the connection electrodes comprises:
a first connection electrode connected to the drain area; and
a second connection electrode connected to the source area.

11. The electronic device of claim 10, further comprising a first conductive pattern and a second conductive pattern, which are disposed between the base substrate and the transistor and are spaced apart from each other when viewed in the plane, wherein the first conductive pattern is electrically connected to the drain area via the first connection electrode, and the second conductive pattern is electrically connected to the source area via the second connection electrode.

12. The electronic device of claim 1, wherein each of the source area and the drain area comprises:
a first portion having a first conductivity; and
a second portion having a second conductivity lower than the first conductivity.

13. The electronic device of claim 12, wherein the protrusion pattern protrudes from the first portion.

14. The electronic device of claim 12, wherein the active area, the first portion, and the protrusion pattern are electrically connected to each other.

15. The electronic device of claim 1, further comprising a light emitting element disposed on the connection electrode and comprising a first electrode connected to the connection electrode, a light emitting layer, and a second electrode, wherein the connection electrode electrically connects the first electrode and the transistor.

16. A electronic device comprising:
a base substrate;
a transistor disposed on the base substrate and comprising a semiconductor pattern comprising a source area, an active area, and a drain area and a gate electrode;
a gate insulating pattern disposed on the semiconductor pattern; and
a connection electrode disposed on the gate insulating pattern and electrically connected to the semiconductor pattern, wherein a first hole extends through the transistor and is disposed adjacent to one of the source area and the drain area, the connection electrode is disposed on a same layer as the gate electrode, a plurality of first holes comprising the first hole are provided, and the connection electrode comprises a protrusion pattern disposed between the first holes.

17. A method of manufacturing an electronic device, comprising:
preparing a preliminary electronic device comprising a base substrate, a preliminary semiconductor pattern disposed on the base substrate and comprising a source area, an active area, and a drain area, and a gate insulating pattern disposed on the preliminary semiconductor pattern;
forming a first opening through the gate insulating pattern to expose a first portion of the preliminary semiconductor pattern;
forming a conductive layer on the gate insulating pattern;
forming a second opening through the conductive layer to expose a portion of the first portion of the preliminary semiconductor pattern and to form a gate electrode and a connection electrode from the conductive layer; and
forming a first hole disposed adjacent to one of the source area and the drain area through the preliminary semiconductor pattern to form a semiconductor pattern from the preliminary semiconductor pattern, wherein the connection electrode comprises a protrusion pattern that protrudes toward the active area when viewed in a plane.

18. The method of claim 17, further comprising doping the first portion of the preliminary semiconductor pattern exposed through the first opening after forming the first opening.

19. The method device of claim 17, wherein the forming of the gate electrode and the connection electrode comprises:
forming a photoresist layer through which a photo opening is defined on the conductive layer; and
etching the conductive layer.

20. The method device of claim 17, wherein the connection electrode is disposed on the gate insulating pattern and electrically connected to the semiconductor pattern, and the connection electrode is disposed on a same layer as the gate electrode.
